(19) United States
(12) Patent Application Publication
(10) Pub. No.: US 2006/0098485 A1
(43) Pub. Date: May 11, 2006

(54) Printable non-volatile passive memory element and method of making thereof

(75) Inventors: Luc Leenders, Herentals (BE); Michel Werts, Antwerpen (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 11/260,832

(22) Filed: Oct. 27, 2005

Related U.S. Application Data
(60) Provisional application No. 60/630,185, filed on Nov. 22, 2004.

(30) Foreign Application Priority Data
Oct. 29, 2004 (EP) 04105412.3

(51) Int. Cl. G11C 16/04

(52) U.S. Cl. 365/185.12

(57) ABSTRACT

Passive memory devices comprising at least one passive memory element and a support having a non-conductive surface on the at least one side provided with the passive memory element, the passive memory element comprising a first electrode system, an insulating system and a second electrode system, wherein the first electrode system is a pattern system; wherein the first electrode is insulated from the second electrode system; wherein at least one conductive bridge is present between the first and the second electrode systems; wherein in the absence of the at least one conductive bridge there is no direct electrical contact between the first and the second patterned electrode systems; and wherein the systems and the conductive bridges are printable using conventional printing processes; and a process for providing a passive memory device, the passive memory device comprising at least one passive memory element and a support, the support having on the at least one side provided with a passive memory element either a non-conductive surface or a patternable conductive layer, the passive memory element comprising a first patterned electrode system, a second patterned electrode system, an insulating system between the first patterned electrode system and the second patterned electrode system and at least one conductive bridge between the first patterned electrode system and the second patterned electrode system, and wherein in the absence of the at least one conductive bridge there is no direct electrical contact between the first and the second electrode systems, comprising the steps of: realizing a first electrode pattern on the non-conductive surface of the support or in the patternable conductive layer on the support, providing an insulating pattern on the first electrode pattern, providing a second electrode pattern on the insulating pattern, and providing electrical contact between the first electrode pattern and the second electrode pattern at predesignated points, wherein at least one of the steps is realized by a conventional printing process.

### CROSS-REFERENCE TO RELATED PATENT APPLICATIONS

This application claims the benefit of U.S. Provisional Application No. 60/630,185 filed Nov. 22, 2004, which is incorporated by reference. In addition, this application claims the benefit of European Application No. 04105412.3 filed Oct. 29, 2004, which is also incorporated by reference.

### FIELD OF THE INVENTION

The present invention concerns a printable passive memory element and method of making same.

### BACKGROUND OF THE INVENTION

There is currently an increasing demand for disposable, inexpensive, flexible, passive memory device-containing tags and labels in which information is stored, for example as anti-counterfeiting tags in packaging. Production of such non-volatile memory elements, including writing of the information, should be easy and inexpensive and preferably should be capable of being incorporated in the tag, label and package printing process or in the packaging process itself and should consist of uncomplicated and inexpensive materials and involve a minimum of processing steps. For use in packages, it is important that the memory device is relatively robust and fairly insensitive to mechanical shock, temperature changes and other environmental influences.

Conventional silicon-based semiconductor memories have the disadvantage of requiring expensive and complex processing, the high process temperatures and the non-flexibility making them unsuitable for use on packaging substrates. Moreover, silicon-based semiconductor memories pose considerable environmental issues upon disposal. U.S. Pat. No. 6,542,397 discloses an apparatus comprising: at least one designated memory cell of a plurality of memory cells, each designated memory cell having a resistance-altering constituent disposed therein, but only exemplifies silicon-based read-only resistor memories. U.S. Pat. No. 6,649,499 discloses a method of making a memory comprising: diffusing of a resistance-altering constituent into a plurality of memory cells, the plurality of memory cells comprising polycrystalline silicon and the resistance-altering constituent comprising at least one Group IA element; and moving at least a portion of an implanted dose of the resistance-altering constituent from the conductive layer of at least one memory cell. In these resistor memories, information is stored by alteration of the resistance at pre-selected crossing points. Crosstalk between adjacent word lines is reduced if the resistance in each memory cell is significantly higher than the resistance of the bit lines and word lines. However, this does not prevent the existence of alternative current paths.

U.S. Pat. No. 6,107,666 discloses a high density ROM device, comprising: a substrate; and at least one memory array, including: a first insulating layer located over a surface of the substrate, plural bit lines located over the first insulating layer and extending in a first direction, said bit lines being spaced from one another at essentially equal intervals; a second insulating layer formed over the plural bit lines, at least one via formed in the second insulating layer and exposing a portion of the bit lines, and plural word lines located over the second insulating layer and extending in a second direction that crosses the first direction to form an angle, said word lines being spaced from one another at essentially equal intervals; and wherein some of the word lines are connected to the bit lines using the via and some of the word lines are isolated from the bit lines using the second insulating layer. U.S. Pat. No. 6,107,666 discloses a read only memory device which is not based on silicon, but in which metal bit lines and word lines are present. Electrical interconnects are made by the application of a metal in pre-selected vias present between the bit lines and word lines.

However, the production processes for the resistor memory cells disclosed in U.S. Pat. No. 6,107,666, U.S. Pat. No. 6,542,397 and U.S. Pat. No. 6,649,499 all rely on evaporation and etching methods to apply the metal or silicon structures, requiring high temperatures in the range of 300° C. to 400° C., which results in melting or severe degradation of polymer-based or paper-based substrates, hence making it unsuitable for packaging. Therefore such metal or silicon structures neither lend themselves to incorporation into tag, label and package printing process or into the packaging process nor do they lend themselves to environmentally friendly disposal.

Information can be stored electrically in a WORM memory by using the anti-fuse principle. U.S. Pat. No. 6,656,763, for example, discloses a method of making an organic memory cell comprising: providing a first electrode; forming a passive layer comprising a conductivity facilitating compound over the first electrode; forming an organic semiconductor layer over the passive layer using a spin-on technique, the spin-on technique comprising applying a mixture of i) at least one of a conjugated organic polymer, a conjugated organometallic compound, a conjugated organometallic polymer, a buckyball, and a carbon nanotube and ii) at least one solvent selected from the group consisting of glycol ether esters, glycol ethers, furans, and alkyl alcohols containing from about 4 to about 7 carbon atoms; and providing a second electrode over the organic semiconductor layer.

Furthermore, US 2004/0149,552A1 discloses an electronic switch comprising: a first conductor; a second conductor; and a conductive organic polymer layer in contact with, and lying between, the first conductor and the second conductor, the conductive organic polymer layer in one of a first state in which the organic polymer layer conducts current between the first conductor and the second conductor with relatively high conductivity, and a second state, in which the organic polymer layer conducts current between the first conductor and the second conductor with relatively lower conductivity. The resistance of a semiconductor layer present between word lines and bit lines can be electrically altered by applying a ‘high’ voltage pulse, thereby increasing the resistance. To prevent alternative current paths it is necessary to include additional layers between the word lines and bit lines in each memory cell to form diodes, hereby making the manufacturing process more complicated.

The printing of memories has been proposed in the art for several different types of devices. US 2003/0230,746A1 discloses a memory device comprising: a first semiconducting polymer film having a first side and a second side, wherein said first semiconducting polymer film includes an organic dopant; a first plurality of electrical conductors substantially parallel to each other coupled to said first side of said first semiconducting polymer layer; and a second plurality of electrical conductors substantially parallel to each other, coupled to said second side of said first semiconducting polymer layer and substantially mutually orthogonal to said first plurality of electrical conductors, wherein an electrical charge is localized on said organic dopant. The structures of the doped semiconducting film, layered between two conducting line patterns are simple. However, these memories are volatile, and the information is lost if no power is applied. US 2001/039124A1 discloses a method for manufacturing a memory device which stores a state in accordance with the presence or the absence of a covering insulating film on a surface of an electrode at a memory cell position, the method comprising: selectively ejecting the insulating material using an inkjet head to the surface of the electrode at a predetermined memory cell position so as to cover the surface of the electrode at the predetermined memory cell position with the insulating material.

WO 02/0029706A1 discloses an electronic bar code comprising: a bar code circuit that stores a code that is electronically readable, wherein the code is defined by a polymer printing process; and an interface coupled to the bar code circuit to allow a bar code reader to access the code stored in the bar code circuit. However, the printed electronic circuit does not consist of a passive matrix but a number of electronic components of which the presence or absence of the component or its connection determines the stored information.

U.S. Pat. No. 5,464,989 discloses a mask ROM having a plurality of memory cells, comprising: a semiconductor substrate having a main surface; a plurality of parallel first signal lines extending in a column direction on said main surface of said semiconductor substrate, a plurality of parallel second signal lines extending in a row direction on said main surface of said semiconductor substrate, crossing said plurality of first signal lines at a plurality of crossovers each forming a respective memory cell of said plurality of memory cells; an insulation film formed between said plurality of first signal lines and said plurality of second signal lines; and selecting means for selecting one of said plurality of first signal lines and one of said plurality of second signal lines and causing electric field between the selected first signal line and the selected second signal line by applying potential difference between the selected first signal line and the selected second signal line, said insulation film having, at each of said plurality of crossovers for storing data, one of i) a first thickness necessary for keeping an insulating state between the selected first signal line and the selected second signal line even if an electric field is received between the first signal line selected by the selecting means and the second signal line selected by the selecting means, ii) a second thickness for causing a first tunnel current to flow between the selected first signal line and the selected second signal line when the electric field is received between the first signal line and the second signal line selected by the selecting means, and iii) a third thickness for causing a second tunnel current to flow between the selected first signal line and the selected second signal line when the electric field is received between the first signal line and the second signal line selected by the selecting means. The production of a passive matrix ROM is thereby disclosed in U.S. Pat. No. 5,464,989 based on conductive electrodes, separated by an isolating oxide film in which a tunnel phenomenon is generated with storage of multiple bit levels in one memory cell. Variations in the oxide layer thickness leads to different tunnel currents through the layer, which encode for multiple levels in the information in each cell.

WO 02/079316A discloses an aqueous composition containing a polymer or copolymer of a 3,4-dialkoxythiophene in which the two alkoxy groups may be the same or different or together represent an optionally substituted oxy-alkylene-oxy bridge, a polyanion and a non-Newtonian binder; a method for preparing a conductive layer comprising: applying the above-described aqueous composition to an optionally subbed support, a dielectric layer, a phosphor layer or an optionally transparent conductive coating; and drying the thereby applied aqueous composition; antistatic and electroconductive coatings prepared according to the above-described method for preparing a conductive layer; a printing ink or paste comprising the above-described aqueous composition; and a printing process comprising: providing the above-described printing ink; printing the printing ink on an optionally subbed support, a dielectric layer, a phosphor layer or an optionally transparent conductive coating. However, WO 02/079316A only discloses the application of such inks for applying antistatic or electroconductive layers to an optionally subbed support, a dielectric layer, a phosphor layer or an optionally transparent conductive layer, which may be a step in the production of electroluminescent devices which can be used in lamps, displays, back-lights e.g. LCD, automobile dashboard and keyswitch backlighting, emergency lighting, cellular phones, personal digital assistants, home electronics, indicator lamps and other applications in which light emission is required.

WO 03/000765A discloses a non-dye containing flexographic ink containing a polymer or copolymer of a 3,4-dialkoxythiophene in which the two alkoxy groups may be the same or different or together represent an optionally substituted oxy-alkylene-oxy bridge, a polyanion and a latex binder in a solvent or aqueous medium, characterized in that the polymer or copolymer of a 3,4-dialkoxythiophene is present in a concentration of at least 0.1% by weight in the ink and that the ink is capable of producing a calorimetrically additive transparent print; a method of preparing the flexographic ink; and a flexographic printing process therewith. However, WO 03/000765A only indicates the application of such inks for applying antistatic and electroconductive patterns to an optionally subbed support, a dielectric layer, a phosphor layer and a transparent conductive layer, which may be a step in the production of electrical circuitry for single and limited use items such as toys, in capacitive antennae as part of radiofrequency tags, in electroluminescent devices which can be used in lamps, displays, back-lights e.g. LCD, automobile dashboard and keyswitch back-lighting, emergency lighting, cellular phones, personal digital assistants, home electronics, indicator lamps and other applications in which light emission is required.

There is therefore a need for an easy and inexpensive means of storing information which can be easily incorporated in a tag, label or package printing process or the packaging process itself. Moreover, such easy and inexpensive means of storing information must be capable of lending itself to environmentally friendly disposal.

### ASPECTS OF THE INVENTION

It is therefore an aspect of the present invention to provide inexpensive non-volatile memory elements.

It is therefore a further aspect of the present invention to realize an easy and inexpensive means of storing information which can be easily incorporated in a tag, label or package printing process or the packaging process itself.

It is a further aspect of the present invention to realize an easy and inexpensive means of storing information which is capable of lending itself to environmentally friendly disposal.

It is a still further aspect of the present invention to realize an electronic device which is characterized in that the bit lines (e.g. first electrode) are provided in the form of a substantially strip-like structure of an electrical conducting or semiconducting material, that the word lines (e.g. second electrode) are provided over the bit lines in the form of a substantially strip-like structure of an electrical conducting or semiconducting material and that an isolating material is provided between the first and second electrode, such that the two electrode planes intersect each other without direct physical and electrical contact, and that an electrical conducting or semiconducting material is provided at pre-selected crossing points of the first and second electrode, contacting both the first and second electrode to make an electrical interconnect (conductive bridge).

Further aspects and advantages of the invention will become apparent from the description hereinafter.

### SUMMARY OF THE INVENTION

It has been surprisingly found that an element comprising a first patterned electrode system, a second patterned electrode system, an insulating system between the first patterned electrode system and the second patterned electrode system and at least one conductive bridge between the first patterned electrode system and the second patterned electrode system, wherein in the absence of the at least one conductive bridge there is no direct electrical contact between the first and the second electrode systems, is printable by conventional printing processes.

Aspects of the present invention are realized by a passive memory element comprising a first electrode system, an insulating system and a second electrode system, wherein the first and second electrode systems are pattern systems; wherein the first electrode is insulated from the second electrode system; wherein at least one conductive bridge is present between the first and the second electrode systems; and wherein the systems and the conductive bridges are printable using conventional printing processes.

Aspects of the present invention are also realized by a first passive memory device comprising at least one passive memory element and a support having a non-conductive surface on the at least one side provided with a passive memory element, the passive memory element comprising a first patterned electrode system, a second patterned electrode system, a patterned insulating system between the first patterned electrode system and the second patterned electrode system, there being at least one conductive bridge between the first patterned electrode system and the second patterned electrode system, wherein in the absence of the at least one conductive bridge there is no direct electrical contact between the first and the second patterned electrode systems; and wherein the passive memory element is printable using conventional printing processes.

Aspects of the present invention have also been realized by a second passive memory device comprising at least one passive memory element and a support having a non-conductive surface on the at least one side provided with the passive memory element, the passive memory element comprising a series of interrupted conducting or semiconducting lines bridged by at least one conductive bridge, wherein the passive memory element is printable using conventional printing processes.

Aspects of the present invention have also been realized by a first process for providing a passive memory device, the passive memory device comprising at least one passive memory element and a support, the support having on the at least one side provided with a passive memory element either a non-conductive surface or a patternable conductive layer, the passive memory element comprising a first patterned electrode system, a second patterned electrode system, an insulating system between the first patterned electrode system and the second patterned electrode system and at least one conductive bridge between the first patterned electrode system and the second patterned electrode system, and wherein in the absence of the at least one conductive bridge there is no direct electrical contact between the first and the second electrode systems, comprising the steps of: realizing a first electrode pattern on the non-conductive surface of the support or in the patternable conductive layer on the support, providing an insulating pattern on the first electrode pattern, providing a second electrode pattern on the insulating pattern, and providing electrical contact between the first electrode pattern and the second electrode pattern at predesignated points, wherein at least one of the steps is realized by a conventional printing process.

Aspects of the present invention have also been realized by a second process for providing a passive memory device, the passive memory device comprising at least one passive memory element and a support, the support having on the at least one side provided with a passive memory element either a non-conductive surface or a patternable conductive layer, the passive memory element comprising a first patterned electrode system, a second patterned electrode system, an insulating system between the first patterned electrode system and the second patterned electrode system and at least one conductive bridge between the first patterned electrode system and the second patterned electrode system, and wherein in the absence of the at least one conductive bridge there is no direct electrical contact between the first and the second electrode systems, comprising the steps of: realizing a first electrode pattern on the non-conductive surface of the support or in the patternable conductive layer on the support, providing an insulating system on the first patterned electrode system, providing a second electrode pattern on the non-conductive surface of a second support or in the patternable conductive layer on the second support, providing conductive pads on the first and/or the second electrode pattern system such than upon bringing the insulating pattern system into contact with the second electrode pattern electrical contact between the first electrode pattern and the second electrode pattern is realized at the predesignated points, and bringing the insulating pattern system in contact with the second electrode pattern system such that electrical contact between the first electrode pattern and the second electrode pattern is realized at the predesignated points, wherein at least one of the steps is realized by a printing process.

Preferred embodiments of the present invention are disclosed in the detailed description of the invention.

### BRIEF DESCRIPTION OF THE DRAWINGS:

FIG. 1a-d illustrate the preparation of a memory device according to an embodiment of the present invention.

FIG. 2a-c illustrates three different methods of storing information in the memory device according to the present invention.

FIG. 3a-c illustrates three different methods to achieve multiple bit-levels in the memory device according to the present invention.

FIG. 4 illustrates the problem of alternative current paths in a 2×2 matrix.

### DETAILED DESCRIPTION OF THE INVENTION

### Definitions

The term passive memory, as used in disclosing the present invention, means a non-volatile memory i.e. read-only memory and is to be distinguished from reversible memories.

The term “support”, as used in disclosing the present invention, means a “self-supporting material” so as to distinguish it from a “layer” which may be coated on a support, but which is itself not self-supporting. It also includes any treatment necessary for, or layer applied to aid, adhesion to the first electrode pattern system.

The term printable, as used in disclosing the present invention, means capable of being printed by conventional impact and/or non-impact printing processes and includes processes in which a conductive surface layer is patterned, for example by oxidation or reduction, during the printing process as disclosed, for example in EP-A 1 054 414, but excludes processes such as evaporation, etching, diffusion processes used in the production of conventional electronics e.g. silicon-based electronics.

The term conventional printing processes, as used in disclosing the present invention, includes but is not restricted to ink-jet printing, intaglio printing, screen printing, flexographic printing, offset printing, stamp printing, gravure printing, electrophotographic, electrographic and thermal and laser-induced processes.

The term impact printing process, as used in disclosing the present invention, means a printing process in which contact is made between the medium in which the print is produced and the printing system e.g. printers that work by striking an ink ribbon such as daisy-wheel, dot-matrix and line printers, and direct thermal printers in which the thermographic material is printed by direct contact with heating elements in a thermal head and printers in which a master is covered with an ink layer on areas corresponding to a desired image or shape, after which the ink is transferred to the medium, such as offset, gravure or flexographic printing.

The term non-impact printing process, as used in disclosing the present invention, means a printing process in which no contact is made between the medium in which the print is produced and the printing system e.g. electrographic printers, electrophotographic printers, laser printers, ink jet printers in which prints are produced without needing to strike the print medium.

The term conductive bridge, as used in disclosing the present invention, means a conductive blob having any shape providing an instantaneous electrical contact between the second electrode pattern system and the first electrode pattern system on a non-conductive surface of a support; or providing an instantaneous electrical contact with the first electrode pattern and instantaneous electrical contact with the second electrode pattern upon realization thereof; or being an integral part of the second electrode pattern system providing an instantaneous electrical contact with the first electrode pattern system on a non-conductive surface of a support; or being an integral part of the first electrode pattern system providing instantaneous electrical contact with the second electrode pattern upon realization thereof.

The term pattern, as used in disclosing the present invention, means a non-continuous layer which can be in any form of lines, squares, circles or any random configuration.

The term layer, as used in disclosing the present invention, means a coating covering the whole area of the entity referred to e.g. a support.

The term metallized support, as used in disclosing the present invention, means a support at least one surface of which is covered with metal by any process known to one skilled in the art e.g. lamination, attachment of metal foil, sputtering and evaporation.

The term insulating layer, as used in disclosing the present invention, is a layer having high electrical resistance used for separating conducting layers, which prevents an undesired flow of current between conducting layers contiguous with either side of the insulating layer and specifically is a layer providing a leak current between two electrodes of <5 μA measured at a voltage of 5V.

The term conductive is related to the electric resistance of the material, the electric resistance of a layer being generally expressed in terms of surface resistance R_{S} (unit Ω; often specified as Ω/square). Alternatively, the conductivity may be expressed in terms of the specific (volume) resistivity R_{V}=R_{S}·d, wherein d is the thickness of the layer, and Rᵥ or ρ is in units of ohm-cm. The term conductive, as used in disclosing the present invention, means a material having a surface resistance of <10⁶ ohm/square, preferably <10⁴ ohm/square or having a specific resistivity of <10² ohm-cm, preferably <1 ohm-cm.

The term crosstalk, as used in disclosing the present invention, means a misinterpretation of a bit attributed to the influence of other bits stored in the passive memory device of the present invention resulting from alternative current paths.

The term intrinsically conductive polymer, as used in disclosing the present invention, means organic polymers which have (poly)-conjugated π-electron systems (e.g. double bonds, aromatic or heteroaromatic rings or triple bonds) and whose conductive properties are not influenced by environmental factors such as relative humidity.

The term transparent, as used in disclosing the present invention, means having the property of transmitting at least 70% of the incident light without diffusing it.

The term flexible, as used in disclosing the present invention, means capable of following the curvature of a curved object such as a drum e.g. without being damaged.

PEDOT, as used in disclosing the present invention, represents poly(3,4-ethylenedioxythiophene).

PSS, as used in disclosing the present invention, represents poly(styrene sulfonic acid) or poly(styrene sulfonate).

PANI, as used in disclosing the present invention, represents polyaniline.

The term cross-bar or matrix, as used in disclosing the present invention, means a structure of two overlaying electrode planes, in which both electrode planes are substantially strip-like and overlap each other at any angle, preferably at an angle greater than 30° and particularly preferably an angle of approximately 90°.

### Passive Memory Element

Aspects of the present invention are realized by a passive memory element comprising a first electrode system, an insulating system and a second electrode system, wherein the first and second electrode systems are pattern systems; wherein the first electrode is insulated from the second electrode system; wherein at least one conductive bridge is present between the first and the second electrode systems; and wherein the systems and the conductive bridges are printable using conventional printing processes.

According to a first embodiment of the passive memory element, according to the present invention, the passive memory element is a matrix memory device.

According to a second embodiment of the passive memory element, according to the present invention, at least two of the first patterned electrode system, the second patterned electrode system and the insulating pattern system between the first patterned electrode system is in the form of a crossbar system, preferably with the insulating pattern system and the second patterned electrode system are both substantially orthogonal in respect of the first patterned electrode system.

According to a third embodiment of the passive memory element, according to the present invention, the passive memory element comprises a first electrode system, an insulating system and a second electrode system, wherein the first electrode system is insulated from the second electrode system, wherein at least one conductive bridge is present between the first and second electrode systems when the first electrode system is a pattern system, wherein the systems and the conductive bridges are printable using conventional printing processes.

### Passive Memory Element—Operation

The present invention provides a passive memory device comprising at least one simple passive memory element, that is producible by printing processes, in which information is stored by providing electrical interconnects (conductive bridges) between word lines and bit lines at pre-selected crossing points. Information is stored by the presence or absence of a conductive bridge between a word line and a bit line. The word lines and bit lines are electrically insulated from each other by an insulating material at the crossing points of the electrodes. By means of printing of a conducting material at a crossing point, a conductive bridge is formed between a word line and a bit line. Readout of the data is accomplished by measuring the resistance between each bit line-word line combination. The resistivity can be read out electrically in contact or capacitively and corresponds to logical values in a binary code.

The structure of the passive memory element in the passive memory device, according to the present invention, preferably comprises a matrix of bit lines and word lines in the form of substantially strip-like structures of an electrically conducting or semiconducting material and comprising an insulating material between the first and second electrodes, such that the two electrode planes intersect each other without direct physical and electrical contact, and comprising an electrical conducting or semiconducting material, provided at pre-selected crossing points of the first and second electrode, contacting both the first and second electrode to make a conductive bridge.

Another aspect of the present invention relates to the retrieval of the covert information in the memory device by subsequent measurement of the resistance between the word lines and bit lines, wherein a low resistance, corresponding to an electrical conductive bridge, denotes one binary state and a high resistance, corresponding to a crossing point without an electrical conductive bridge, denotes a second binary state.

As may be recognized by those skilled in the art, no diode structures are present at the crossing points, thereby allowing alternative current paths to be formed. In the passive memory element, according to the present invention, a voltage is applied between one selected word line and one selected bit line. If no conductive bridge is present at the predesignated crossing point between the selected word line and the selected bit line, no or a relatively small current will flow. However, if conductive bridges are present at predesignated crossing points in the passive memory element, the current may flow via an alternative pathway through three or more conductive bridges. This phenomenon is described for example in U.S. Pat. No. 6,055,180. One way to circumvent this issue is to employ rectifying diodes at each conductive bridge. Unfortunately, achieving this by traditional techniques is complicated and gives no competitive advantage over active-matrix memories and passive matrix memories. Alternatively, one might not use rectifying diodes and allow alternative current paths. Careful selection of the crossing points at which a conductive bridge is created can prevent alternative current paths. This limits the amount of information stored but is acceptable for those applications where a low information content is sufficient. In the event that the resistance of the conductive bridges is significantly higher than the resistance of the bit lines and word lines, discrimination between a ‘true’ conductive bridge at a crossing point and a false reading due to an alternative current path through three conductive bridges which will result in a smaller current is possible.

### Passive Memory Device—Configuration

Aspects of the present invention are also realized by a first passive memory device comprising at least one passive memory element and a support having a non-conductive surface on the at least one side provided with a passive memory element, the passive memory element comprising a first patterned electrode system, a second patterned electrode system, a patterned insulating system between the first patterned electrode system and the second patterned electrode system, there being at least one conductive bridge between the first patterned electrode system and the second patterned electrode system, wherein in the absence of the at least one conductive bridge there is no direct electrical contact between the first and the second patterned electrode systems; and wherein the systems and the conductive bridges are printable using conventional printing processes.

Aspects of the present invention have also been realized by a second passive memory device comprising at least one passive memory element and a support having a non-conductive surface on the at least one side provided with a passive memory element, the passive memory element comprising a series of interrupted conducting or semiconducting lines bridged by at least one conductive bridge, wherein the passive memory element is printable using conventional printing processes.

According to a first embodiment of the passive memory devices, according to the present invention, the passive memory element is a matrix memory device.

According to a second embodiment of the passive memory devices, according to the present invention, at least two of the first patterned electrode system, the second patterned electrode system and the insulating pattern system between the first patterned electrode system is in the form of a crossbar system, preferably with the insulating pattern system and the second patterned electrode system are both substantially orthogonal in respect of the first patterned electrode system.

According to a third embodiment of the passive memory devices, according to the present invention, the support and second support can be a flexible or rigid plastic, glass, paper, board, carton or a composite material of any of these materials.

According to a fourth embodiment of the passive memory devices, according to the present invention, the electrode is a conducting or semiconducting material, which can be applied by a printing process or is the conductive surface of a metallic or metallized support. Suitable conductive and semiconductive materials include conductive inks based on conductive metals (e.g. silver paste), conductive metal alloys, conductive metal oxides, semiconductive metal oxides and intrinsically conductive organic polymers (e.g. polyaniline, PEDOT), carbon black. Conductive inks based on intrinsically conductive organic polymers are preferred with inks based on PEDOT:PSS being particularly preferred due to its low absorption of visible light. Suitable metallic supports are aluminium sheets, copper sheets and stainless steel sheets.

According to a fifth embodiment of the passive memory devices, according to the present invention, at least one of the first patterned electrode system, the second patterned electrode system and the insulating system between the first patterned electrode system, and the at least one conductive bridge is transparent.

According to a sixth embodiment of the passive memory devices, according to the present invention, at least one of the first and second patterned electrode systems and the at least one conductive bridge comprises an inorganic conducting medium, e.g. a metal, a semiconducting metal oxide and carbon, or an organic conducting medium, e.g. an intrinsically conductive organic polymer.

According to a seventh embodiment of the passive memory devices, according to the present invention, at least one of the first and second patterned electrode systems and the at least one conductive bridge comprises an organic conducting medium, which is an intrinsically conductive organic polymer.

According to an eighth embodiment of the passive memory devices, according to the present invention, at least one of the first and second patterned electrode systems and the at least one conductive bridge comprises a polythiophene, a polyaniline or a polypyrrole.

According to a ninth embodiment of the passive memory devices, according to the present invention, at least one of the first and second patterned electrode systems and the at least one conductive bridge comprises a poly(3,4-dioxyalkylenethiophene).

According to a tenth embodiment of the passive memory devices, according to the present invention, at least one of the first and second patterned electrode systems and the at least one conductive bridge comprises poly(3,4-dioxyethylenethiophene).

According to an eleventh embodiment of the passive memory devices, according to the present invention, at least one of the first and second patterned electrode systems and the at least one conductive bridge comprises carbon.

According to a twelfth embodiment of the passive memory devices, according to the present invention, at least one of the first and second patterned electrode systems and the at least one conductive bridge comprises a metal e.g. silver or gold.

According to a thirteenth embodiment of the passive memory devices, according to the present invention, at least one of the first and second patterned electrode systems and the at least one conductive bridge comprises a semiconducting metal oxide or doped metal oxide e.g. vanadium pentoxide, indium tin oxide or a metal antimonate.

The conductivity of the electrodes and conductive bridges needs to be sufficient to have a current flowing through a conductive bridge that is significantly higher than the current measured through a crossing point without a conductive bridge. The resistance is preferably in the range of 1 to 100,000 Ohm per square and more preferably lower than 20,000 Ohm per square. The line width of the electrodes can be in the range from 5 to 1000 μm and more preferably from 100 to 500 μm. The line width of the isolating strips can be in the range from 10 to 10000 μm and more preferably from 100 to 5000 μm.

The position of the ‘conductive bridges’ in the memory device may be different for each device, thus storing personalized/individual information, such as name, address, date of birth, etc or a products' manufacturing date/time and pricing.

According to a fourteenth embodiment of the passive memory devices, according to the present invention, the passive memory device is transparent, thereby becoming almost invisible to the unaided eye. This can be realized by using for example PEDOT:PSS as the conductive material for the electrodes and ‘conductive bridges’, and by using a transparent isolating material, for example a transparent UV-curable ink.

According to a fifteenth embodiment of the passive memory devices, according to the present invention, the ‘conductive bridges’ are coloured, for example black by using a carbon black-based ink.

According to a sixteenth embodiment of the passive memory devices, according to the present invention, to visually hide the location of the ‘conductive bridges’, non-conducting black bridges may be printed on the remaining crossing points without conductive bridges. The conducting and non-conducting bridges may have any colour, for example by adding dyes or pigments.

According to a seventeenth embodiment of the passive memory devices, according to the present invention, the memory device is overprinted with an image or homogeneously coloured or opaque layer to visually hide the location of the ‘conductive bridges’.

According to an eighteenth embodiment of the passive memory devices, according to the present invention, a coloured or opaque foil is laminated over the memory device to visually hide the location of the ‘conductive bridges’.

According to a nineteenth embodiment of the passive memory devices, according to the present invention, the passive memory devices may be combined with one or more security features e.g. security inks based on magnetic, infrared-absorbing, thermochromic, photochromic, coin-reactive, optically variable, fluorescent or phosphorescent compounds and the like, chemical or biological taggants based on isotopes, DNA, antibodies or specific detectable ingredients and the like can be included in one of the layers of the memory device. The memory device may be overcoated or overprinted with a hologram, tamper proof security film, a barcode or the like. The memory device, according to the present invention, may be printed on security paper.

According to a twentieth embodiment of the passive memory devices, according to the present invention, the number of conductive bridges is at least two.

According to a twenty-first embodiment of the passive memory devices, the support is a non-metallic or non-metallized support.

According to a twenty-second embodiment of the passive memory devices, according to the present invention, the memory device is exclusive of metallic silicon.

According to a twenty-third embodiment of the first passive memory device, according to the present invention, the first passive memory device comprises a non-metallic or non-metallized support and on at least one side of the support a passive memory element, the passive memory element comprising a first patterned electrode system, a second patterned electrode system, a patterned insulating system between the first patterned electrode system and the second patterned electrode system, there being at least one conductive bridge between the first patterned electrode system and the second patterned electrode system, wherein the passive memory element is producible using conventional printing processes and is exclusive of silicon metal and in the absence of the at least one conductive bridge there is no direct electrical contact between the first and the second patterned electrode systems.

According to a twenty-third embodiment of the second passive memory device, according to the present invention, the second passive device is exclusive of silicon, the second passive memory device comprising a non-metallic or non-metallized support provided on at least one side thereof with a passive memory element, the passive memory element comprising a series of interrupted conducting or semiconducting lines bridged by at least one conductive bridge, wherein the passive memory element is printable using conventional printing processes.

### Insulating Systems

The term insulating system, as used in disclosing the present invention, means a permanently insulating system i.e. a system whose properties are unchangeable under normal ambient conditions, whose resistance is unalterable by applying high voltage electrical pulses and excludes semiconducting layers whose conductivity can be influenced by doping, such as disclosed in U.S. Pat. No. 6,656,763, and conductive organic polymer layers whose conductivity state can change upon the application of a relatively large voltage differential between a first and a second electrode contiguous each continuous with one of the sides of the insulating system, such as disclosed in US 2004/0149552A1.

Suitable insulation materials are inorganic and organic materials e.g. polymeric materials such as homopolymers and copolymers selected, for example, from the group consisting of acrylates, olefins, methacrylates, acrylamides, methacrylamides, acrylonitrile, vinyl chloride, vinyl alcohol, vinylidene chloride, vinyl fluoride, vinylidene fluoride, other fluorinated ethylene compounds, vinyl alcohol, vinyl acetals, vinyl acetate, styrene and butadiene; inorganic fillers, such as silica, alumina, alumina hydrates, and inorganic fibres, such as glass fibres. The insulating system can also be a UV-curable ink or varnish.

### Processes for Producing the Memory Passive Device

Aspects of the present invention have been realized by first process for providing a passive memory device, the passive memory device comprising a support and a passive memory element on at least one side of the support, the passive memory element comprising a first patterned electrode system, a second patterned electrode system, an insulating system between the first patterned electrode system and the second patterned electrode system and at least one conductive bridge between the first patterned electrode system and the second patterned electrode system, and wherein in the absence of the at least one conductive bridge there is no direct electrical contact between the first and the second electrode systems, comprising the steps of: realizing a first electrode pattern on the non-metallic or non-metallized support, providing an insulating pattern on the first electrode pattern, providing a second electrode pattern on the insulating pattern, and providing electrical contact between the first electrode pattern and the second electrode pattern at predesignated points, wherein at least one of the steps is realized with a conventional printing process.

Aspects of the present invention have also been realized by a second process for providing a passive memory device, the passive memory device comprising a non-metallic or non-metallized support and a passive memory element on at least one side of the support, the passive memory element comprising a first patterned electrode system, a second patterned electrode system, an insulating system between the first patterned electrode system and the second patterned electrode system and at least one conductive bridge between the first patterned electrode system and the second patterned electrode system, and wherein in the absence of the at least one conductive bridge there is no direct electrical contact between the first and the second electrode systems, comprising the steps of: realizing a first electrode pattern on the non-metallic or non-metallized support, providing an insulating system on the first patterned electrode system, providing a second electrode pattern on a second non-metallic or non-metallized support, providing electrical contacts on the first or second electrode pattern system such than upon bringing the insulating pattern system into contact with the second electrode pattern electrical contact between the first electrode pattern and the second electrode pattern is realized at the predesignated points, and bringing the insulating pattern system in contact with the second electrode pattern system such that electrical contact between the first electrode pattern and the second electrode pattern is realized at the predesignated points, wherein at least one of the steps is realized with a printing process. The contact between the insulating pattern system and the second electrode system may be temporary, such as in a touch application, or permanent, such as is the case of lamination.

All the layers in the memory device, bit lines, insulating pattern system, word lines and ‘conductive bridges’, can be applied by conventional printing processes including but not restricted to ink-jet printing, intaglio printing, screen printing, flexographic printing, offset printing, stamp printing, gravure printing and thermal and laser-induced processes. Either one printing process can be used for all the layers in the memory device, or a combination of two or more printing processes can be used.

According to a first embodiment of the processes, according to the present invention, the process includes at least one printing step.

According to a second embodiment of the processes, according to the present invention, the conventional printing process is a non-impact printing process e.g. ink-jet printing, electrophotographic printing and electrographic printing.

According to a third embodiment of the processes, according to the present invention, the conventional printing process is an impact printing process e.g. offset printing, screen printing, flexographic printing, and stamp printing.

According to a fourth embodiment of the processes, according to the present invention, the conventional printing process is selected from the group consisting of ink-jet printing, intaglio printing, screen printing, flexographic printing, offset printing, stamp printing, gravure printing, electrophotographic printing, electrographic printing and thermal and laser-induced processes.

According to a fifth embodiment of the processes, according to the present invention, the first electrode pattern, the insulating pattern, the second electrode pattern and the at least one conductive bridge are performed by ink-jet printing.

According to a sixth embodiment of the processes, according to the present invention, the first electrode pattern, the insulating pattern, the second electrode pattern and the at least one conductive bridge are performed by flexographic printing.

According to a seventh embodiment of the processes, according to the present invention, the passive memory device is exclusive of metallic silicon.

According to an eighth embodiment of the first process, according to the present invention, the provision of the electrical contact between the first patterned electrode system and the second patterned electrode system is realized in the same process step as the printing of the second patterned electrode e.g. directly between the second electrode pattern system and the first electrode pattern system through openings in the insulating pattern system or via a pre-existing conductive bridge to the first electrode pattern system or conductive bridges coprinted with the second electrode pattern system.

According to a ninth embodiment of the first process, according to the present invention, the first electrode pattern, the insulating pattern, the second electrode pattern and the at least one conductive bridge are each performed by a printing process which can be the same or different.

According to a tenth embodiment of the first process, according to the present invention, the first electrode pattern, the insulating pattern, the second electrode pattern and the at least one conductive bridge are performed by the same printing process.

According to an eleventh embodiment of the first process, according to the present invention, the conductive bridge can be realized in the same process step as the first electrode pattern system, the second electrode pattern system or the insulating pattern system.

According to a twelfth embodiment of the first process, according to the present invention, the step of storing the information by applying conductive bridges on pre-selected crossing points between the first electrode pattern and the second electrode pattern is performed in the same printing line as that providing the first electrode pattern system, the insulating pattern system and the second electrode pattern system.

According to a thirteenth embodiment of the first process, according to the present invention, the step of storing the information by applying conductive bridges on pre-selected crossing points between the first electrode pattern and the second electrode pattern is not performed in the same printing line as that providing the first electrode pattern, the insulating pattern and the second electrode pattern.

Printing according to the process, according to the present invention, can be carried out directly on a package, on a label, a ticket, an ID-card, a bank card, a legal document and banknotes. The memory device may act as an identification system, a security feature, an anti-counterfeiting feature, etc.

The passive memory element, according to the present invention, can be produced in an inexpensive way by reel-to-reel printing. The printing process consists of at least three steps, a) printing of the bit lines of a first electrode on a substrate thereby realizing the first electrode pattern, b) printing of the lines of an insulating material on the first electrode thereby realizing the insulating pattern, and c) optionally printing of the word lines of a second electrode on the insulating material thereby realizing the second electrode pattern, such that the two electrode planes intersect each other without direct physical and electrical contact. Information is then stored either by the separate printing of a conducting material at pre-selected crossing points to form conductive bridges or the information is stored together with the printing of the first electrode pattern, second electrode pattern or insulating pattern steps in the printing of the passive memory element.

Such an off-line step of storing the information by applying conductive bridges on pre-selected crossing points between the first electrode pattern and the second electrode pattern can be carried out by, for example, ink-jet printing, at the same or at a different location, at the same time or at a later time. This enables the personalization of each passive memory element with different information.

According to a fourteenth embodiment of the first process, according to the present invention, at least the first electrode pattern, the insulating pattern and the second electrode pattern are realized by reel to reel printing.

According to a fifteenth embodiment of the first process, according to the present invention, the support is a non-metallic or non-metallized support.

According to a sixteenth embodiment of the first process, according to the present invention, the first process for providing a passive memory device exclusive of silicon metal, the passive memory device comprising a support and a passive memory element on at least one side of the support, the passive memory element comprising a first patterned electrode system, a second patterned electrode system, an insulating system between the first patterned electrode system and the second patterned electrode system and at least one conductive bridge between the first patterned electrode system and the second patterned electrode system, wherein in the absence of the at least one conductive bridge there is no direct electrical contact between the first and the second electrode systems, comprises the steps of: realizing a first electrode pattern on the non-metallic or non-metallized support, providing an insulating pattern on the first electrode pattern, providing a second electrode pattern on the insulating pattern, and providing electrical contact between the first electrode pattern and the second electrode pattern at predesignated points, wherein at least one of the steps is realized with a conventional printing process.

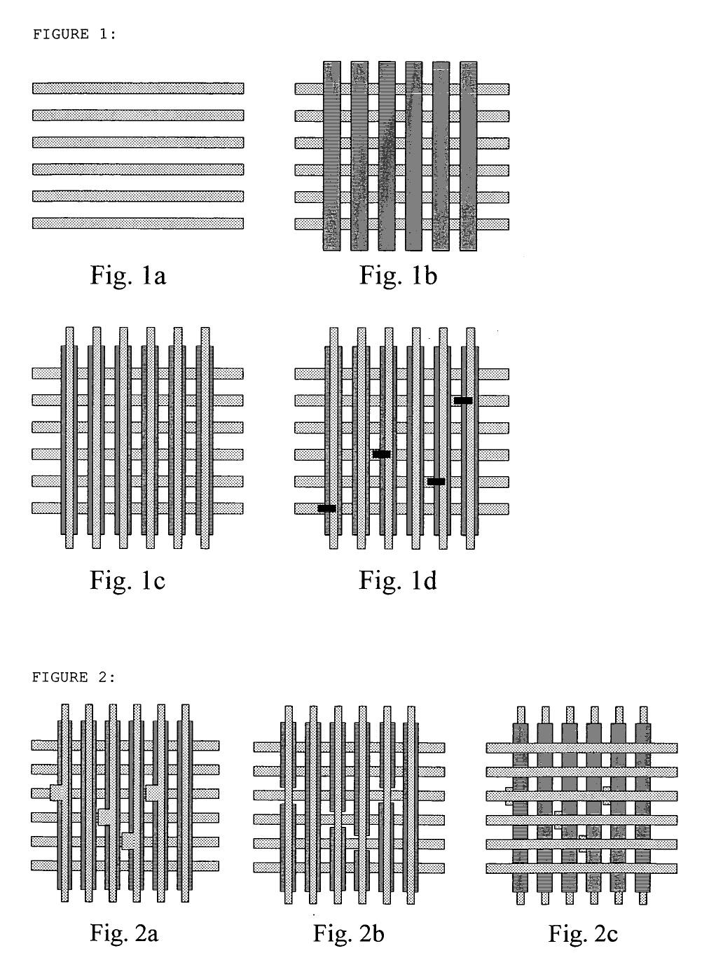

The passive memory element, according to the present invention, is producible by a printing process. Information can be stored by creating conductive bridges via a printing process. FIG. 1 is a schematic representation of such a printing process for the manufacturing of a passive memory, according to the present invention. The printing process can be divided into four printing steps that are performed sequentially, for example in one printing machine with four printing stations.

In the first step (FIG. 1a), strips of a conducting or semiconducting material (bit lines) are printed on a suitable substrate and subsequently dried. Any number of strips can be printed e.g. between 1 and 1000, a single strip resulting in a one-dimensional matrix.

In the second step (FIG. 1b), a pattern of an isolating material is printed on top of the first electrode in such a way that the first electrode is partially covered by the isolating material. The isolating material is also applied by a printing process and can be a solvent-based, water-based or UV-curable ink or a solution of an inorganic, organic or polymeric material in a suitable solvent and is subsequently dried or cured.

In the third step (FIG. 1c), strips of a conducting or semiconducting material (word lines) are printed on the isolating strips and subsequently dried. The strips are positioned on the isolating pattern, so that there is no physical and electrical contact between the first and second electrodes. The conducting or semiconducting material can be the same as or different from the conducting or semiconducting material of the first electrode. A device built up out of these three layers can be referred to as an ‘empty’ memory that does not contain any data. These ‘empty’ memories can be printed on one physical location, after which the fourth step, the writing/printing of information in the memory device, is done at another physical location or at a later time.

In the fourth step (FIG. 1d) the information is stored inside the memory by printing ‘conductive bridges’ of a conducting or semiconducting material at pre-selected crossing points in the matrix. Each pixel is positioned so that it (partially) overlaps both the first electrode and the second electrode at the pre-selected crossing point, hereby creating an electrical interconnect or conductive bridge. The conducting or semiconducting material can be the same or different from the conducting or semiconducting material of the electrodes.

FIG. 2 shows another embodiment in which the information is printed together with one of the first three printing steps. In FIG. 2a, the first electrode and isolating material are printed as described in the first embodiment. The second electrode pattern consists of a pattern of electrode word lines and ‘conductive bridges’ combined in one print. This eliminates an additional printing step in writing the information, but depending upon the printing technique used, it may or may not be possible to store different data in each memory device e.g. it is possible if ink-jet printing is used for printing the second electrode. Alternatively, the information can be stored during the printing of the insulating pattern (FIG. 2b) by not printing the isolating material at each crossing point, hereby creating conductive bridges at these locations when the second electrode is printed. As a third option, the information can also be printed together with the first electrode (FIG. 2c). This pattern is similar to the first option, but the three layers are printed in the reverse order.

In another embodiment, information is stored in the memory device by a combination of two or more printing steps, for example one part of the information is printed with the first electrode and a second part together with the second electrode, or one part of the information is printed together with the second electrode or the isolating layer and a second part is printed in a separate printing step in which additional ‘conductive bridges’ are printed. The first part of information might contain fixed information such as the name of a manufacturer, while the second part is variable, such as the production date or batch number.

According to a seventeenth embodiment of the first process, according to the present invention, in a further step one or more of the at least one conductive bridges on pre-selected crossing points between the first electrode pattern and the second electrode pattern are rendered inoperative. This can be done in a chemical, thermal, electrical, mechanical or optical way. Since conductive bridges can be created and removed, the memory device then becomes rewritable.

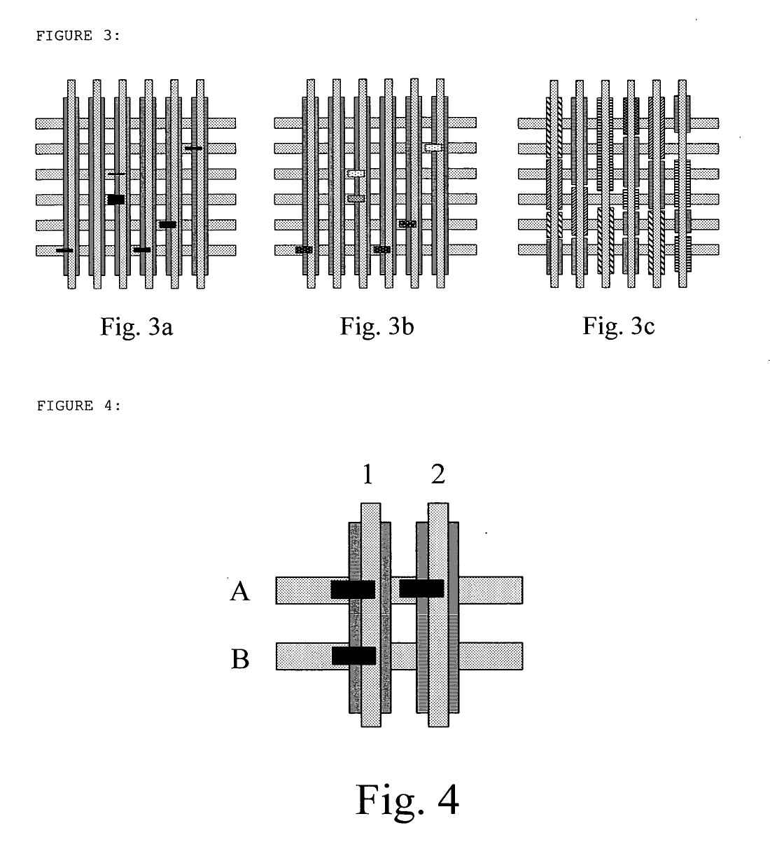

FIG. 3 shows another embodiment in which multiple bit levels are created by varying the conductivity of the conductive bridges. In one embodiment, the multiple bit levels are created by printing ‘conductive bridges’ with different conductivity. This can be achieved by varying the size or thickness of the ‘conductive bridges’ (FIG. 3a) or by varying the intrinsic conductivity of the conducting material (FIG. 3b), used for the ‘conductive bridges’ by changing its chemical composition. In another embodiment, multiple bit levels are created by varying the conductivity of the isolating material, achieved by differences in the layer thickness or chemical composition (FIG. 3c).

The amount of information that can be stored in a memory device of the preferred embodiment (FIG. 2) is limited because of alternative current paths. Measurement of the resistance through the crossing point B2 (via contact point B and contact point 2) in FIG. 4 should show a high resistance, since there is no conductive bridge present. However, current will flow from bit line B to word line 2 via an alternative pathway, namely via the subsequent crossing points B1, A1 and A2. To prevent the alternative current paths, it is necessary to prevent configurations of the conductive bridges as shown in FIG. 4, in which one conductive bridge is present at a crossing point between a bit line and word line and at least one more conductive bridge is present at both these bit lines and word lines. For a 2 2 matrix with 4 bits, the maximum theoretical number of possible combinations is 2⁴=16 combinations. Due to alternative current paths, only 12 combinations can be used without false readings due to alternative current paths. In a 5 5 matrix with 25 bits, only 27 thousand of the possible 33.5 million theoretical combinations can be used and in a 8 8 matrix with 64 bits, only about 1 billion of the possible 10¹⁹ theoretical combinations can be used. This will be sufficient for most applications. In case a higher information density is necessary, the size of the matrix can be increased or multiple matrices can be used, positioned next to or on top of each other.

According to a twenty-first embodiment of the first passive memory device, according to the present invention, the size of the matrix is increased or multiple matrices can be used, positioned next to or on top of each other.

According to an eighth embodiment of the second process, according to the present invention, the support and the second support are independently a non-metallic or a non-metallized support.

According to a ninth embodiment of the second process, according to the present invention, the second process for providing a passive memory device exclusive of silicon metal, the passive memory device comprising a non-metallic or non-metallized support and a passive memory element on at least one side of the support, the passive memory element comprising a first patterned electrode system, a second patterned electrode system, an insulating system between the first patterned electrode system and the second patterned electrode system and at least one conductive bridge between the first patterned electrode system and the second patterned electrode system, wherein in the absence of the at least one conductive bridge there is no direct electrical contact between the first and the second electrode systems, comprises the steps of: realizing a first electrode pattern on the non-metallic or non-metallized support, providing an insulating system on the first patterned electrode system, providing a second electrode pattern on a second non-metallic or non-metallized support, providing electrical contacts on the first or second electrode pattern system such than upon bringing the insulating pattern system into contact with the second electrode pattern electrical contact between the first electrode pattern and the second electrode pattern is realized at the predesignated points, and bringing the insulating pattern system in contact with the second electrode pattern system such that electrical contact between the first electrode pattern and the second electrode pattern is realized at the predesignated points, wherein at least one of the steps is realized with a printing process.

In a further embodiment of the passive memory device, according to the present invention, the conductivity of the conductive bridges can be selected to be significantly lower than the conductivity of the electrode lines. One can distinguish between a ‘true’ conductive bridge and a measured conductive bridge due to alternative current paths. Since the current flows via an alternative current path through three conductive bridges (resistances) instead of one, a difference in current can be detected. The conductivity of the electrode lines needs to be significantly higher to diminish additional resistances in the electrode lines which are dependent on the distance over which the current flows, hereby making the analysis of the read currents more complicated.

### Conductive Screen Printing Inks

WO-A 02/079316 discloses an aqueous composition containing a polymer or copolymer of a 3,4-dialkoxythiophene in which the two alkoxy groups may be the same or different or together represent an optionally substituted oxy-alkylene-oxy bridge, a polyanion and a non-Newtonian binder; a method for preparing a conductive layer comprising: applying the above-described aqueous composition to an optionally subbed support, a dielectric layer, a phosphor layer or an optionally transparent conductive coating; and drying the thereby applied aqueous composition; antistatic and electroconductive coatings prepared according to the above-described method for preparing a conductive layer; a printing ink or paste comprising the above-described aqueous composition; and a printing process comprising: providing the above-described printing ink; printing the printing ink on an optionally subbed support, a dielectric layer, a phosphor layer or an optionally transparent conductive coating. The screen printing ink formulations disclosed in WO-A 02/079316 are specifically incorporated herein by reference.

WO-A 03/048228 discloses a method for preparing a composition containing between 0.08 and 3.0% by weight of polymer or copolymer of a 3,4-dialkoxythiophene in which the two alkoxy groups may be the same or different or together represent an optionally substituted oxy-alkylene-oxy bridge, a polyanion and at least one non-aqueous solvent from a dispersion of the polymer or copolymer of (3,4-dialkoxythiophene) and the polyanion in water which is prepared in the substantial absence of oxygen, comprising in the following order the steps of: i) mixing at least one of the non-aqueous solvents with the aqueous dispersion of the polymer or copolymer of (3,4-dialkoxythiophene) and the polyanion; and ii) evaporating water from the mixture prepared in step i) until the content of water therein is reduced by at least 65% by weight; a printing ink, printing paste or coating composition, capable of yielding layers with enhanced conductivity at a given transparency, prepared according to the above-described method; a coating process with the coating composition thereby producing a layer with enhanced conductivity at a given transparency; and a printing process with the printing ink or paste thereby producing a layer with enhanced conductivity at a given transparency. The screen printing ink formulations disclosed in WO-A 03/048228 are specifically incorporated herein by reference.

WO-A 03/048229 discloses a method for preparing a composition containing between 0.08 and 3.0% by weight of a polymer or copolymer of a 3,4-dialkoxythiophene in which the two alkoxy groups may be the same or different or together represent a oxy-alkylene-oxy bridge optionally substituted with substituents selected from the group consisting of alkyl, alkoxy, alkyoxyalkyl, carboxy, alkylsulphonato, alkyloxyalkylsulphonato and carboxy ester groups, a polyanion and at least one polyhydroxy non-aqueous solvent from a dispersion of the polymer or copolymer of (3,4-dialkoxythiophene) and the polyanion in water comprising in the following order the steps of: i) mixing at least one of the non-aqueous solvents with the aqueous dispersion of the polymer or copolymer of (3,4-dialkoxythiophene) and the polyanion; and ii) evaporating water from the mixture prepared in step i) until the content of water therein is reduced by at least 65% by weight; a printing ink, printing paste or coating composition, capable of yielding layers with an enhanced transparency at a given surface resistance, prepared according to the above-described method; a coating process with the coating composition thereby producing a layer with enhanced transparency at a given surface resistance; and a printing process with the printing ink or paste thereby producing a layer with enhanced transparency at a given surface resistance. The screen printing ink formulations disclosed in WO-A 03/048229 are specifically incorporated herein by reference.

### Conductive Flexographic Printing Inks

WO-A 03/000765 discloses a non-dye containing flexographic ink containing a polymer or copolymer of a 3,4-dialkoxythiophene in which the two alkoxy groups may be the same or different or together represent an optionally substituted oxy-alkylene-oxy bridge, a polyanion and a latex binder in a solvent or aqueous medium, characterized in that the polymer or copolymer of a 3,4-dialkoxythiophene is present in a concentration of at least 0.1% by weight in the ink and that the ink is capable of producing a calorimetrically additive transparent print; a method of preparing the flexographic ink; and a flexographic printing process therewith. The flexographic printing ink formulations disclosed in WO-A 03/000765 are specifically incorporated herein by reference.

### Conductive Ink-jet Inks

Formulations containing a polymer or copolymer of a 3,4-dialkoxythiophene in which the two alkoxy groups may be the same or different or together represent an optionally substituted oxy-alkylene-oxy bridge, a polyanion and a high boiling point liquid in a solvent or aqueous medium can be prepared, which are suitable for ink-jet printing. Critical properties, such as the viscosity, which at the jetting temperature is preferably in the range of 3 to 15 mPa.s for a Universal Print Head (from AGFA-GEVAERT), can be adjusted by changing the concentration of conductive polymer and the amount and type of high boiling point liquid. A 1.2% by weight dispersion of PEDOT:PSS has a viscosity of approximately 30 mPa.s at room temperature and a 0.6% by weight dispersion has a viscosity at room temperature of approximately 10 mPa.s.

The surface tension is preferably in the range of 28 to 36 mN/m under jetting conditions for a Universal Print Head, and can be adjusted by adding appropriate anionic, cationic or non-ionic surfactants or solvents, e.g. alcohols. Surfactants can also influence the jetting performance, wetting properties of the ink on a substrate and the UV-stability of printed layers.

The addition of, for example, 5 to 20% by weight of high boiling point liquids improves the conductivity of the printed layer after drying; useful high boiling point liquids include ethylene glycol, diethylene glycol, propylene glycol, glycerol, N-methylpyrrolidone and 2-pyrrolidone. The choice of high boiling point liquid also has an influence on drying time, minimum drying temperature, jetting performance, wetting properties, viscosity and surface tension.

Optionally, volatile bases, such as dimethylethanolamine, triethylamine or diisopropylethylamine might be added to neutralize the inkjet printing solution to prevent corrosion of the print head.

### INDUSTRIAL APPLICATION

The passive memory devices, according to the present invention, can be used in security and anti-counterfeiting applications e.g. in tickets, labels, tags, an ID-card, a bank card, a legal document, banknotes and packaging and can also be integrated into packaging.

The invention is illustrated hereinafter by way of comparative examples and invention examples. The percentages and ratios given in these examples are by weight unless otherwise indicated.

Subbing layer Nr. 01 on the emulsion side of the support:

| | |
|---|---|
| copolymer of 88% vinylidene chloride, 10% methyl | 79.1 mg/m² |
| acrylate and 2% itaconic acid | |
| Kieselsol ® 100F, a colloidal silica from BAYER | 18.6 mg/m² |
| Mersolat ® H, a surfactant from BAYER | 0.4 mg/m² |
| Ultravon ® W, a surfactant from CIBA-GEIGY | 1.9 mg/m² |

Commercial coatings used in the elements of the INVENTION EXAMPLES:
ORGACON EL-P3040, a PEDOT:PSS screen printing ink from AGFA-GEVAERT N.V.;
AGORIX® MAGENTA INK, a UV-hardenable ink-jet ink from AGFA-DOTRIX N.V.;
ECCOCOAT® CC-2, a silver paste from EMERSON & CUMING;
ED4000, a carbon black ink from ELECTRA POLYMERS;
NORIPET® 093 Clear, an insulating screen printing ink from Proll
   Ingredients used in non-commercial coatings used in the elements of the INVENTION EXAMPLES:
TANACOTE® FG3, an aqueous carboxylated polypropylene emulsion from SYBRON CHEMICALS;
PANIPOL® W, a 6% by weight aqueous dispersion of polyaniline from PANIPOL LTD.;
DYNOL® 604, an acetylenic glycol-based surfactant from AIR PRODUCTS;
POLYESTER DISPERSION, is a 25% by weight aqueous dispersion of a polyester of 52.9 mol % terephthalic acid, 40 mol % terephthalic acid, 7 mol % sulfo-isophthalic acid, 0.1 mol % of 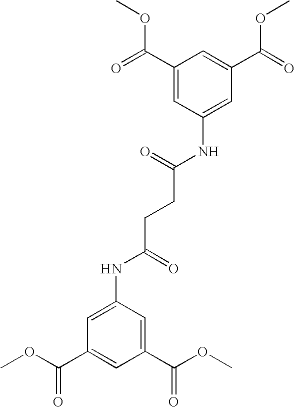
   and 100 mol % ethylene glycol;
PVP=KOLLIDON® 90, a polyvinylpyrrolidone from BASF.

### INVENTION EXAMPLE 1

### Fully Ink-jet Printed Element

The passive memory element of INVENTION EXAMPLE 1 was produced by first ink-jet printing the first electrode pattern with 8 lines 30 mm in length, 1 mm wide and 2 mm apart using a Universal Printhead (from AGFA-GEVAERT) with a PEDOT:PSS ink-jet ink with the composition given below onto a 125 μm thick polyethylene terephthalate support coated with a 1% solution of PVP in 1:1 mixture of deionized water and ethanol (with a 20 μm coating knife) to adjust the surface energy of the polyethylene terephthalate support.

| | Concentration |
|---|---|
| PEDOT: PSS 1.1% aqueous dispersion | 57.10% |
| Deionized water | 28.55% |
| N-methyl pyrrolidone | 14.20% |
| Dynol ® 604 | 0.15% |
| Dimethylethanolamine | to increase pH to 7-8 |

The insulating pattern with 8 lines 30 mm in length, 1 mm wide and 2 mm apart in a direction perpendicular with respect to the first electrode pattern was then realized by ink-jet printing two layers of AGORIX Magenta INK on top of one another using the Universal Printhead followed by UV-curing.

The second electrode pattern with 8 lines 30 mm in length, 1 mm wide and 2 mm apart was then produced by ink-jet printing with the above-described PEDOT:PSS ink-jet ink on top of the lines of the insulating pattern using the Universal Printhead.

Finally ‘conductive bridges’ of PEDOT:PSS were applied by inkjet printing of lines of 1×3 mm using the Universal Printhead with the above-described PEDOT:PSS ink-jet ink at pre-selected crossing points to form the conductive bridges. The resistance between a bit line and word line was measured with a Fluke Multimeter and was approximately 1 MOhm for a conductive bridge and higher than 30 MOhm if no conductive bridge was present.

### INVENTION EXAMPLE 2

### Combination of Flexographic and Ink-jet Printing

The passive memory element of INVENTION EXAMPLE 2 was produced by printing the first electrode pattern with 8 lines 25 mm in length, 1 mm wide and 2 mm apart at 18 m/min on a non-pretreated PET-substrate with a Rotary Koater Pilot Press (from R.K. Print Coat Instruments, Ltd.) using a flexographic PEDOT:PSS ink (composition given below) and then drying in an oven at 109° C. in a roll to roll process.

| | Concentration |
|---|---|
| PEDOT: PSS 3% | 45.0% |
| Deionized water | 14.0% |
| Polyester dispersion | 5.6% |
| Tanacote ® FG3 | 1.4% |
| 1,2-propaandiol | 1.6% |
| Diethylene glycol monomethyl ether | 2.9% |
| Diethylene glycol (DEG) | 4.5% |
| Dibutyl sebacate | 5.0% |
| isopropanol | 20.0% |

A primer layer was then flexographically printed on the first electrode pattern using a 5% solution of PVP in a 1:1 mixture of water and ethanol using a ESIPROOF flexographic handproofer (from R.K. Print Coat Instruments, Ltd.) and dried at 100° C. for 5 minutes.

Two layers of AGORIX Magenta INK were printed using the Universal Printhead on top of one another as 8 lines 30 mm in length, 2.5 mm wide and 1 mm apart in a direction perpendicular with respect to the first electrode pattern and then UV-cured, thereby forming an insulating line pattern.

The second electrode pattern with 8 lines 30 mm in length, 1 mm wide and 2.5 mm apart was produced by ink-jet printing with a PEDOT:PSS ink-jet ink (composition given above) on top of the insulating layer.

‘Conductive bridges’ of PEDOT:PSS were then inkjet printed as 8 lines 3 mm in length and 1 mm wide on pre-selected crossing points using the Universal Printhead with the above-described PEDOT:PSS ink-jet ink to form the conductive bridges. The resistance between a bit line and word line was measured with a Fluke Multimeter and was approximately 1 MOhm for a conductive bridge and was higher than 30 MOhm if no conductive bridge was present.

### INVENTION EXAMPLE 3

The passive memory element of INVENTION EXAMPLE 3 was produced as described for the passive memory element of INVENTION EXAMPLE 2 except that the conductive bridges were made manually with ‘conductive bridges’ of ED4000 (carbon black ink), PANIPOLO W (polyaniline dispersion) and ECCOCOAT® CC (silver paste) on pre-selected crossing points instead of by ink-jet printing.

The resistance between a bit line and word line was measured with a Fluke Multimeter and measured to be 0.5 to 1.5 MOhm for all conductive bridges, whereas a resistance of greater than 30 MOhm was measured if no conductive bridge was present.

### INVENTION EXAMPLE 4

### Screen Printed Element with Manually Applied Conductive Bridges

The passive memory element of INVENTION EXAMPLE 4 was produced by screen printing the first electrode pattern with 8 lines 30 mm in length, 1 mm wide and 2 mm apart on a 125 μm thick polyethylene terephthalate support subbed with subbing layer nr. 01 using ORGACON® EL-P3040 (a PEDOT:PSS screen printing ink), thereby forming the first electrode pattern.

After drying for 3 minutes at 130° C., NORIPET® 093 Clear (an insulating ink) was applied by screen printing as 8 insulating lines 30 mm in length and 2 mm wide each spaced 1 mm apart, in a direction perpendicular with respect to the first electrode lines, and dried for 3 minutes at 130° C. thereby forming the insulating layer pattern. The second electrode pattern was then produced by screen printing ORGACON® EL-P3040 on top of the insulating lines in lines 30 mm in length and 1 mm wide each 2 mm apart, thereby forming a 8 8 matrix.

‘Conductive bridges’ of ED4000 (carbon black ink), Panipol® W (polyaniline dispersion) and ECCOCOAT® CC2 (silver paste) were then applied to pre-selected crossing points to form the conductive bridges. Readout was carried out by positioning the memory element on a printed circuit board with contacts that corresponded to the electrode contacts on the memory element. A voltage of 5 volt was applied between two contacts (one bit line and one word line) and the current was measured. Selection of the bit line and word line was performed using multiplexers. Crossing points without a conductive bridge gave an average current of 3 μA, the currents measured through the conductive bridges were approx. 100 μA for carbon black, 80 μA for the polyaniline and 60 μA for silver.

### INVENTION EXAMPLE 5

### Fully Screen Printed Element

The passive memory element of INVENTION EXAMPLE 5 was prepared as described in INVENTION EXAMPLE 4, except that PEDOT:PSS conductive bridges were screen printed together with the second electrode in one pattern instead of the manual application of carbon black, polyaniline or silver paste. Measurement of the currents as described in INVENTION EXAMPLE 4 gave a current of approx. 3 μA for crossing points without a conductive bridge and 80-100 μA at crossing points with a conductive bridge. False readings due to alternative current paths exhibited a current of approximately 60 μA.

### INVENTION EXAMPLE 6

The passive memory element of INVENTION EXAMPLE 6 was prepared as described for INVENTION EXAMPLE 4, except that the second electrode pattern was applied manually with PANIPOL W (polyaniline dispersion). Conductive bridges were made with ED4000 (carbon black ink) and Panipol W. The resistance between a bit line and word line was measured with a Fluke Multimeter and was 700 kOhm for a PANI conductive bridge, 300 kOhm for a carbon black conductive bridge, both being lower than the 30 MOhm measured if no conductive bridge was present.

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

Having described in detail preferred embodiments of the current invention, it will now be apparent to those skilled in the art that numerous modifications can be made therein without departing from the scope of the invention as defined in the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

We claim:

1. A passive memory element comprising a first electrode system, an insulating system and a second electrode system, wherein said first electrode system is a pattern system; wherein said first electrode is insulated from said second electrode system; wherein at least one conductive bridge is present between said first and said second electrode systems; and wherein said systems and said conductive bridges are printable using conventional printing processes.

2. A first passive memory device comprising at least one passive memory element and a support having a non-conductive surface on the at least one side provided with said passive memory element, said passive memory element comprising a first patterned electrode system, a second patterned electrode system, a patterned insulating system between said first patterned electrode system and said second patterned electrode system, there being at least one conductive bridge between said first patterned electrode system and said second patterned electrode system, wherein in the absence of said at least one conductive bridge there is no direct electrical contact between said first and said second patterned electrode systems; and wherein said systems and said conductive bridges are printable using conventional printing processes.

3. The first device according to claim 2, wherein at least two of said first patterned electrode system, said second patterned electrode system and said insulating system between said first patterned electrode system is in the form of a crossbar or matrix system.

4. The first device according to claim 3, wherein the size of the matrix is increased or multiple matrices can be used, positioned next to or on top of each other.

5. The first device according to claim 2, wherein at least one of said first patterned electrode system, said second patterned electrode system and said insulating system between said first patterned electrode system, and said at least one conductive bridge is transparent.

6. The first device according to claim 2, wherein said first passive memory device is transparent.

7. The first device according to claim 2, wherein said conductive bridges are coloured.

8. The first device according to claim 2, said passive memory device is overprinted with an image or a homogeneously coloured or opaque layer to visually hide the location of said conductive bridges.

9. The first device according to claim 2, a coloured or opaque foil is laminated over said passive memory device to visually hide the location of said conductive bridges.

10. The first device according to claim 2, wherein at least one of said first and second patterned electrode systems comprises a inorganic conducting medium or an organic conducting medium.

11. The first device according to claim 10, wherein said organic conducting medium is an intrinsically conductive organic polymer.

12. The first device according to claim 11, wherein said intrinsically conductive organic polymer is a polythiophene, a polyaniline or a polypyrrole.

13. The first device according to claim 11, wherein said polythiophene is a poly(3,4-dioxyalkylenethiophene).

14. The first device according to claim 11, wherein said polythiophene is poly(3,4-dioxyethylenethiophene).

15. A second passive memory device comprising at least one passive memory element and a support having a non-conductive surface on the at least one side provided with said passive memory element, said passive memory element comprising a series of interrupted conducting or semiconducting lines bridged by at least one conductive bridge, wherein said passive memory element is printable using conventional printing processes.

16. A first process for providing a passive memory device, said passive memory device comprising at least one passive memory element and a support, the support having on the at least one side provided with a passive memory element either a non-conductive surface or a patternable conductive layer, said passive memory element comprising a first patterned electrode system, a second patterned electrode system, an insulating system between said first patterned electrode system and said second patterned electrode system and at least one conductive bridge between said first patterned electrode system and said second patterned electrode system, and wherein in the absence of said at least one conductive bridge there is no direct electrical contact between said first and said second electrode systems, comprising the steps of: realizing a first electrode pattern on the non-conductive surface of the support or in the patternable conductive layer on the support, providing an insulating pattern on the first electrode pattern, providing a second electrode pattern on the insulating pattern, and providing electrical contact between the first electrode pattern and the second electrode pattern at predesignated points, wherein at least one of the steps is realized by a conventional printing process.

17. The first process according to claim 16, wherein said provision of said second patterned electrode is realized in the same process step as said electrical contact between said first patterned electrode system and said second patterned electrode system.

18. The first process according to claim 16, wherein said conventional printing process is a non-impact printing process.

19. The first process according to claim 16, wherein said conventional printing process is an impact printing process.

20. The first process according to claim 16, wherein said conventional printing process is selected from the group consisting of ink-jet printing, intaglio printing, screen printing, flexographic printing, offset printing, stamp printing, gravure printing, electrophotographic printing, electrographic printing and thermal and laser-induced processes.

21. The first process according to claim 16, wherein in a further step one or more of said at least one conductive bridge on pre-selected crossing points between said first electrode pattern and said second electrode pattern are rendered inoperative.

22. The first process for providing a passive memory device according to claim 16, wherein said support is a non-metallic or non-metallized support.

23. The first process for providing a passive memory device according to claim 16, wherein said passive memory device is exclusive of metallic silicon.

24. A second process for providing a passive memory device, said passive memory device comprising at least one passive memory element and a support, the support having on the at least one side provided with a passive memory element either a non-conductive surface or a patternable conductive layer, said passive memory element comprising a first patterned electrode system, a second patterned electrode system, an insulating system between said first patterned electrode system and said second patterned electrode system and at least one conductive bridge between said first patterned electrode system and said second patterned electrode system, and wherein in the absence of the at least one conductive bridge there is no direct electrical contact between said first and said second electrode systems, comprising the steps of: realizing a first electrode pattern on said non-conductive surface of said support or in said patternable conductive layer on said support, providing an insulating system on said first patterned electrode system, providing said second electrode pattern on a non-conductive surface of a second support or in a patternable conductive layer on said second support, providing conductive pads on said first and/or said second electrode pattern system such than upon bringing the insulating pattern system into contact with said second electrode pattern electrical contact between said first electrode pattern and said second electrode pattern is realized at predesignated points, and bringing said insulating pattern system in contact with said second electrode pattern system such that electrical contact between said first electrode pattern and said second electrode pattern is realized at said predesignated points, wherein at least one of said steps is realized by a printing process.

25. The second process for providing a passive memory device according to claim 24, wherein said support and said second support is independently a non-metallic or non-metallized support.

26. The second process for providing a passive memory device according to claim 24, wherein said passive memory device is exclusive of metallic silicon.
